(19) United States
(12) Patent Application Publication
(10) Pub. No.: US 2024/0224728 A1
(43) Pub. Date: Jul. 4, 2024

(54) DISPLAY DEVICE

(71) Applicant: LG Display Co., Ltd., Seoul (KR)

(72) Inventors: Taehee KO, Seoul (KR); Sunghee PARK, Goyang-si (KR)

(73) Assignee: LG Display Co., Ltd., Seoul (KR)

(21) Appl. No.: 18/398,432

(22) Filed: Dec. 28, 2023

(30) Foreign Application Priority Data
Dec. 30, 2022 (KR) 10-2022-0191258
Dec. 15, 2023 (KR) 10-2023-0183666

(51) Int. Cl. H10K 59/80; H10K 59/131; H10K 59/88

(52) U.S. Cl. CPC H10K 59/873; H10K 59/131; H10K 59/88

(57) ABSTRACT

A display device includes a display panel including a display area, a non-display area surrounding the display area, and a non-pad area located outside the display area; a dam-applied area disposed in the non-display area to surround the display area; a gate driver disposed in at least one side of the non-display area; and an overcoat layer disposed in the display area and the non-pad area, and on the gate driver, wherein the gate driver includes a gate driving circuit and a dummy gate driving circuit.

### CROSS-REFERENCE TO RELATED APPLICATIONS

This application claims the priorities of Korean Patent Application No. 10-2022-0191258 filed on Dec. 30, 2022 and Korean Patent Application No. 10-2023-0183666 filed on Dec. 15, 2023, which are hereby incorporated by reference in their entirety.

### BACKGROUND

### Field of the Disclosure

The present disclosure relates to a display device, and more particularly, to a display device capable of blocking a moisture invasion path into an organic light-emitting element to improve reliability of the organic light-emitting element.

### Description of the Background

A display device is applied to various electronic devices such as TVs, mobile phones, laptops and tablets. To this end, research to develop thinning, lightening, and low power consumption of the display device is continuing.

The display device may include a liquid crystal display device (LCD), a plasma display panel device (PDP), a field emission display device (FED), an electrowetting display device (EWD), and an organic light-emitting display device (OLED).

The organic light-emitting display device (OLED) includes a plurality of pixel areas arranged in a display area where an image is displayed, and a plurality of organic light-emitting elements corresponding to the plurality of pixel areas. The organic light-emitting element is a self-emitting light-emitting element. Thus, the organic light-emitting display device has the advantages of fast response speed, high luminous efficiency, and high luminance and a large viewing angle, and excellent contrast ratio and color gamut, compared to the liquid crystal display device.

The organic light-emitting element includes an organic material that may be easily deteriorated by moisture or the like. Accordingly, research is being conducted on a scheme of blocking a penetration path of moisture to prevent the deterioration of the organic material.

Further, demand for a display device in which multiple display devices are arranged to implement a large-area screen, and a display device with various sizes is increasing. Accordingly, it has become an important issue to block the moisture penetration path of the organic light-emitting element to improve the quality of the display device while implementing the display device of various sizes.

### SUMMARY

Accordingly, the present disclosure is directed to a display device that substantially obviates one or more of problems due to limitations and disadvantages described above.

More specifically, the present disclosure is to provide a display device which is cuttable to implement the display device of various sizes, and blocks the moisture invasion path as one of the causes of deterioration of the organic light-emitting element, thereby maintaining performance of the organic light-emitting element.

The present disclosure is also to provide a display device in which when even when an undercut structure disposed under an overcoat layer to block the moisture invasion path is disposed in the same layer as a layer in which a dummy gate driving circuit is disposed, metal wiring lines are arranged in a distributed manner and correspondingly, an integrated pattern array is divided into distributed portions, and components of the dummy gate driving circuit are electrically connected to each other via the metal wiring lines.

The present disclosure is also to provide a display device in which the dummy gate driving circuit is disposed in a dam formation area to prevent a size of an area where reliability may be secured in a corner bezel area from being reduced.

Further, the present disclosure is to provide a display device in which a corner bezel area and a non-pad area bezel area have the same pattern array structure for blocking a moisture invasion path. Thus, the moisture invasion path to the display area may be blocked to improve the reliability of the display device.

The present disclosure is not limited to the above-mentioned. Other advantages according to the present disclosure that are not mentioned may be understood based on following descriptions, and may be more clearly understood based on aspects according to the present disclosure. Further, it will be easily understood that the advantages according to the present disclosure may be realized using means shown in the claims or combinations thereof.

To achieve these and other advantages and in accordance with the present disclosure, as embodied and broadly described, a display device includes a display panel including a display area, a non-display area surrounding the display area, and a non-pad area located outside the display area; a dam-applied area disposed in the non-display area to surround the display area; a gate driver disposed in at least one side of the non-display area; and an overcoat layer disposed in the display area and the non-pad area, and on the gate driver, wherein the gate driver includes a gate driving circuit and a dummy gate driving circuit.

According to one aspect of the present disclosure, in the display device which is cuttable to implement the display device of various sizes, the moisture invasion path as one of the causes of deterioration of the organic light-emitting element may be blocked, thereby maintaining performance of the organic light-emitting element and improving a lifespan of the organic light-emitting element.

Maintaining of the performance of the organic light-emitting element and improving of the lifespan of the organic light-emitting element may maintain an image quality in a display device even at low power, thereby reducing power consumption.

Further, in the display device which is cuttable to implement the display device of various sizes, the size of the area where reliability may be secured in the corner bezel area disposed in the non-pad area may be prevented from being reduced such that an area in which the non-pad bezel area and the corner area bezel area may have the same pattern array structure for blocking the moisture invasion path may be secured. Accordingly, the moisture invasion path to the display area may be blocked, thereby securing the reliability of the display device.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions below.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic plan view of a display device according to an aspect of the present disclosure;

FIG. 2 is an enlarged plan view showing a portion of a non-pad area of the display device according to an aspect of the present disclosure;

FIG. 3 is a cross-sectional view along line 3-3 in FIG. 2;

FIG. 4 is a cross-sectional view along line 4-4 in FIG. 2;

FIG. 5 is an enlarged plan view of area 5 in FIG. 2;

FIG. 6 is a cross-sectional view along line 6-6 in FIG. 5;

FIG. 7 is an enlarged plan view of a portion of a non-pad area of a display device according to another aspect of the present disclosure;

FIG. 8 is a cross-sectional view along a line 8-8 in FIG. 7;

FIG. 9 is an enlarged view of area 9 in FIG. 7;

FIG. 10 is a cross-sectional view along line 10-10 in FIG. 7; and

FIG. 11 is an enlarged cross-sectional view of area 11 in FIG. 10.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various aspects are illustrated and described further below. It will be understood that the description herein is not intended to limit the claims to the specific aspects described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for describing aspects of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated.

When a certain aspect may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “aspects,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing aspects.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each aspect of the present disclosure will be described with reference to the accompanying drawings

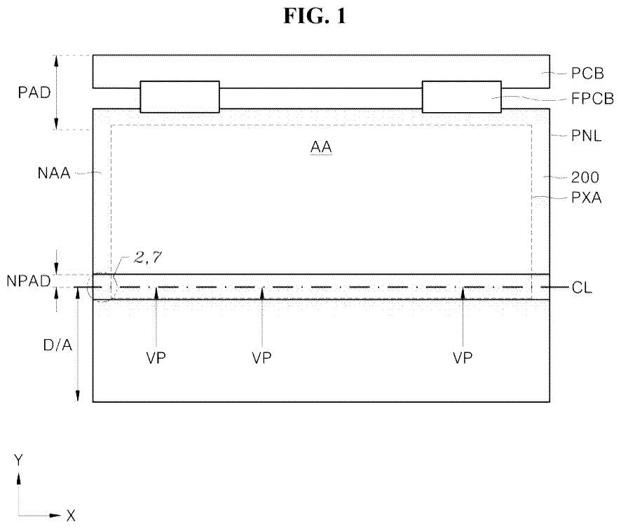

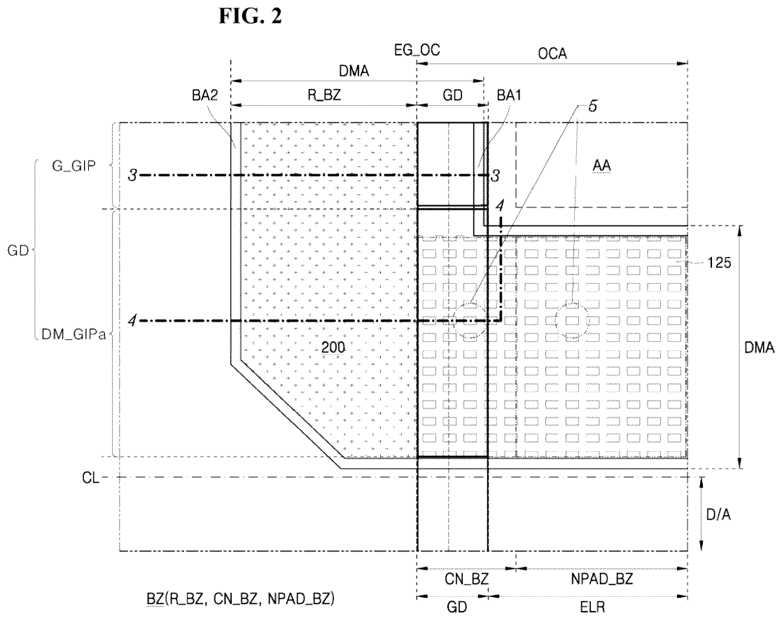

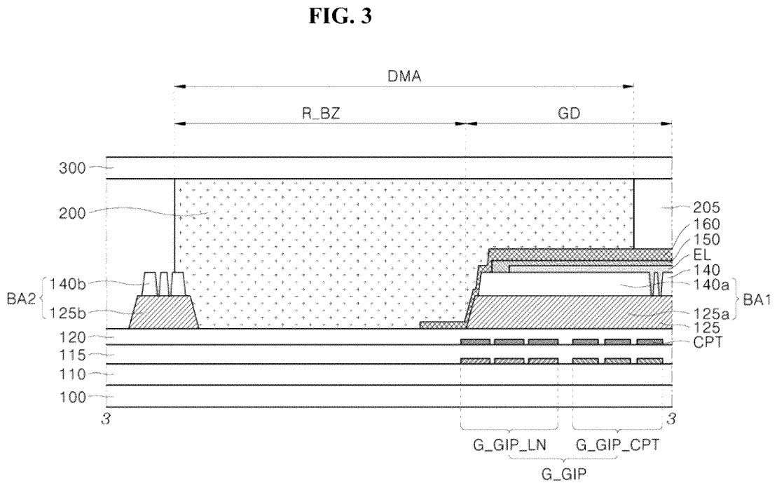

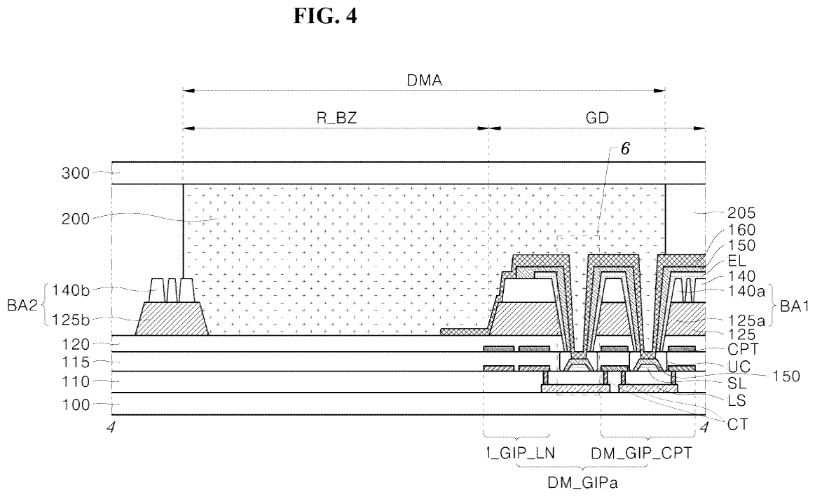

FIG. 1 is a schematic plan view of a display device according to an aspect of the present disclosure. FIG. 2 is a plan view showing an enlarged portion of a non-pad area of a display device according to one aspect of the present disclosure. For example, FIG. 2 is an enlarged plan view of area 2 in FIG. 1. FIG. 3 is a cross-sectional view taken along line 3-3 in FIG. 2. FIG. 4 is a cross-sectional view taken along line 4-4 in FIG. 2.

FIG. 1 shows only a display panel PNL, a dam pattern 200, a printed circuit board PCB, and a flexible printed circuit board FPCB among various components of the display device for convenience of illustration.

Referring to FIG. 1 to FIG. 4, the display panel PNL of the display device according to the present disclosure may include a display area AA, a non-display area NAA, a pad area PAD, and a non-pad area NPAD.

The display panel PNL may include a first substrate 100 and a second substrate 300 bonded to each other. The first substrate 100 may be made of a transparent material. For example, the first substrate 100 may include glass or plastic. The second substrate 300 may be bonded to the first substrate 100 via a transparent filling member 205. The transparent filling member 205 may include optically clear resin (OCR). The second substrate 300 may be made of a transparent material. For example, the second substrate 300 may include glass or plastic.

The display area AA is an area where an image is displayed, and may include a plurality of sub-pixels. The display device according to an aspect of the present disclosure may be embodied as a transparent display device that displays an image and transmits light therethrough so that an object in rear of the display panel PNL may be recognized by a user in front of the display panel PNL.

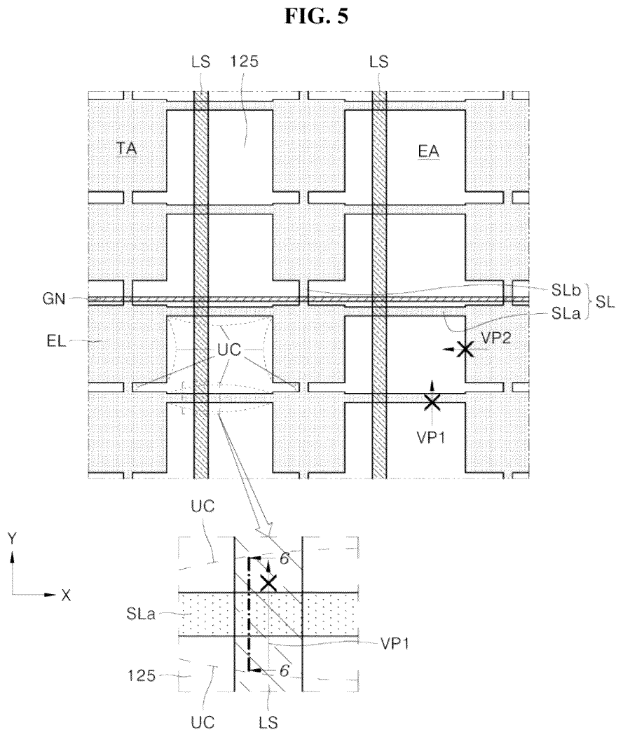

In one of schemes for implementing the transparent display panel PNL, a plurality of sub-pixels may be divided into a transmissive area and a display region, wherein light may transmit the transmissive area so that an object in rear of the display panel PNL may be recognized by the user in front thereof. To this end, the transmissive area may be an area in which an opaque material or a reflective material is not disposed. In addition, an organic material layer as a light-emitting layer may be disposed in each of the transmissive area and the display region. The transmissive areas and the display region will be described in detail with reference to FIG. 5 later.

Each of the sub-pixels disposed in the display area AA includes an area emitting light corresponding to a single color. Three or four or more sub-pixels adjacent to each other and corresponding to different colors among the plurality of sub-pixels may constitute one pixel emitting light of various colors.

Based on combination of light beams respectively emitted from two or more adjacent sub-pixels that constitute any one pixel area, the pixel area may render various colors and emit an image to the display area AA. For example, the sub-pixels constituting one pixel area may respectively emit light beams corresponding to green (G), blue (B), and red (R), or may respectively emit light beams corresponding to green (G), blue (B), red (R), and white (W). Each of the plurality of sub-pixels may include a thin-film transistor and an organic light-emitting element connected to the thin-film transistor. The thin-film transistor may include a semiconductor layer, a gate electrode, and source/drain electrodes. The organic light-emitting element may include an anode electrode, a cathode electrode, and an organic material layer (or an organic light-emitting layer) disposed between the anode electrode and the cathode electrode. The anode electrode may also be referred to as a first electrode, and the cathode electrode may also be referred to as a second electrode. The anode electrode of the organic light-emitting element may be electrically connected to the source/drain electrodes of the thin-film transistor.

The non-display area NAA may be disposed to surround the display area AA and may be an area where an image is not displayed. The non-display area NAA may include a bezel area BZ. The bezel area BZ may be located along and in an edge of the display panel PNL and may include a reliable bezel area R_BZ, a non-pad bezel area NPAD_BZ, and a corner bezel area CN_BZ.

The pad area PAD may be an area disposed in the non-display area NAA other than the display area AA and may be area in which the flexible printed circuit board FPCB and the printed circuit board PCB are disposed. The flexible printed circuit board FPCB and the printed circuit board PCB may be disposed on at least one side edge of the display panel PNL. An integrated circuit chip may be disposed on the flexible printed circuit board FPCB.

The flexible printed circuit board FPCB may be coupled to the printed circuit board PCB and thus may receive power and various signals for operating the organic light-emitting element from the printed circuit board PCB and may supply the same to the display area AA. For example, the various signals may include a high-potential voltage, a low-potential voltage, a scan signal, or a data signal.

The printed circuit board PCB may supply the signals to the integrated circuit chip disposed on the flexible printed circuit board FPCB. Various parts for supplying the various signals to the integrated circuit chip may be disposed on the printed circuit board PCB. In FIG. 1, the printed circuit board PCB is shown as a single printed circuit board. However, the present disclosure is not limited thereto. For example, a plurality of printed circuit boards PCB may be arranged on and along one side edge of the display panel PNL.

The non-pad area NPAD may be disposed on the non-display area NAA excluding the display area AA, and may be positioned on the other side of the display panel PNL opposite to the pad area PAD disposed on one side of the display panel PNL. The other side edge opposite to the pad area PAD of the display panel PNL may have a cutting line CL disposed therein.

As the demand for the display device with various sizes increases, research thereon is being conducted. In this regard, there is a scheme of introducing a cuttable display panel PNL. In the display panel PNL that is cuttable, the cutting line CL is defined. A removal target area D/A is separated and removed when the display panel PNL is cut along the cutting line CL. A portion of the other side edge area opposite to the pad area PAD of the display panel PNL except for the removal target area D/A removed along the cutting line CL may be the non-pad area NPAD. The removal target area D/A may be removed from the display panel PNL along the cutting line CL, such that a target size of the display device to be implemented may be achieved.

In the display panel in which the size of the display device is fixed, a sub-pixel is disposed only in the display area AA. However, in the cuttable display panel PNL, an area PXA in which a plurality of sub-pixels is disposed may extend to the non-pad area NPAD. In other words, a plurality of transmissive areas and a plurality of display areas, each including an organic material layer, may be disposed in the non-pad area NPAD.

The organic material layer may be easily deteriorated by moisture or oxygen. Thus, an area in which the organic material layer is disposed in the other side edge of the display panel PNL where the non-pad area NPAD is positioned may act as a moisture invasion path. A moisture invasion path direction VP along which the moisture invades may be a direction from the other side edge of the display panel PNL to the display area AA, as indicated by an arrow in FIG. 1. Further, along a direction in which the organic material layer is disposed in a portion of the non-pad area NPAD facing in the moisture invasion path direction VP, the moisture may invade the display area AA. Thus, the moisture may penetrate into the display area AA along a direction in which the organic material layer is disposed. Accordingly, it is important to prevent penetration of the moisture or oxygen through the organic material layer disposed along the moisture invasion path direction VP.

To this end, one aspect of the present disclosure may include a configuration in which the organic material layer disposed on the non-pad area NPAD is discontinuous, as one of schemes to prevent moisture or oxygen from invading the display area AA. The description thereof will be made below with reference to the drawings.

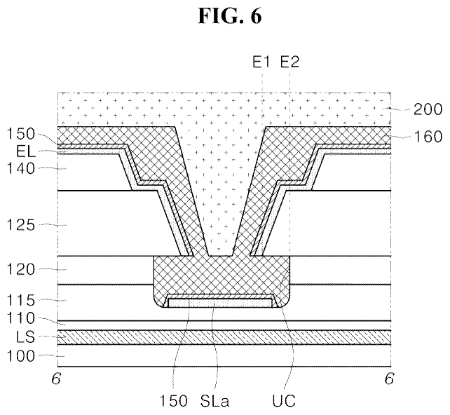

FIG. 5 is an enlarged plan view of an area 5 in FIG. 2. FIG. 6 is a cross-sectional view along line 6-6 in FIG. 5.

Referring to FIG. 5 and FIG. 6 along with FIG. 2, in the cuttable display panel PNL, an area PXA where a plurality of pixels is disposed may be disposed to extend to the non-pad area NPAD. Accordingly, the non-pad area NPAD may include a plurality of transmissive areas TA and a plurality of display regions EA. The transmissive area TA may be an area where no opaque or reflective material is disposed. The plurality of transmissive areas TA may be arranged to be spaced apart from each other while the display region EA is disposed therebetween. The transmissive areas TA may be arranged to be spaced apart from each other in a first direction (for example, an X-axis direction), and a second direction (for example, a Y-axis direction) different from the first direction of the display panel PNL (see FIG. 1).

In the display region EA of the non-pad area NPAD, the first substrate 110 may include a first metal wiring line LS and a second metal wiring line GN. The first metal wiring line LS may be disposed in the non-pad bezel area NPAD_BZ or in the corner bezel area CN_BZ while constituting a light blocking layer in the display area AA. However, aspects of the present disclosure are not limited thereto. For example, while the first metal wiring line LS constitutes the source/drain electrode in the display area AA, the first metal wiring line LS including the same material as that of the source/drain electrode may be disposed in the non-pad bezel area NPAD_BZ or the corner bezel area CN_BZ. The first metal wiring line LS may extend along a longitudinal direction thereof as the second direction in which the transmissive areas TA are arranged. The second metal wiring line GN may extend in the first (X-axis) direction that intersects the first metal wiring line LS extending in the second (Y-axis) direction. The second metal wiring line GN may be disposed in the non-pad bezel area NPAD_BZ or the corner bezel area CN_BZ while constituting the gate electrode in the display area AA. However, aspects of the present disclosure are not limited thereto.

A buffer layer 110, an interlayer insulation layer 115, a passivation layer 120, an overcoat layer 125, a bank 140, an organic material layer EL, a cathode electrode 150, and a capping layer 160 may be disposed on the first metal wiring line LS. Each of the buffer layer 110 and the interlayer insulating layer 115 disposed on the first metal wiring line LS may be formed as an insulating film and may have a single-layer or multi-layer structure. The buffer layer 110 and the interlayer insulating layer 115 may be formed to cover the gate electrode of the thin-film transistor in the display area AA and may extend to the non-pad bezel area NPAD_BZ or the corner bezel area CN_BZ.

The passivation layer 120 may be disposed on the interlayer insulating layer 115, and the overcoat layer 125 may be disposed on the passivation layer 120. The passivation layer 120 may include an insulating film made of oxide. The overcoat layer 125 may planarize a step caused by underlying various circuit elements disposed in the display panel PNL. The overcoat layer 125 may be made of a photoactive compound (PAC).

In FIG. 5, for convenience of illustration, the organic material layer EL is shown to be disposed only in the transmissive area TA. However, the organic material layer EL may be disposed across an entire area of the display device. In one example, the organic material layer EL may be disposed in an organic material formation area ELR, as shown in FIG. 2. Accordingly, the organic material layer EL may be disposed on a portion of the overcoat layer 125 of the display region EA.

As the organic material layer EL is disposed on the portion of the overcoat layer 125 of the display region EA, a slit line SL may be formed between adjacent transmissive areas TA, thereby ensuring reliability of the display device. The slit line SL may include a first slit line SLa and a second slit line SLb. For example, when a periphery of the transmissive area TA is surrounded only with the overcoat layer 125, a problem may occur where moisture invades into the display area AA through the organic material layer EL disposed on the overcoat layer 125.

To prevent the moisture from invading the display area AA, an undercut structure UC may be disposed under the overcoat layer 125 in the display region EA. Specifically, the undercut structure UC may be located along a border of the transmissive area TA. The undercut structure UC may isolate portions of the overcoat layer 125 from each other and prevent a situation in which the periphery of the transmissive area TA is surrounded only with the overcoat layer 125. When the undercut structure UC has been formed under the overcoat layer 125, and then, the organic material layer EL is stacked thereon, the organic material layer EL may be discontinuous such that portions of the organic material layer EL respectively in adjacent transmissive areas TA may be isolated from each other, and thus, the first slit line SLa and the second slit line SLb may be formed. For example, the first slit line SLa may be disposed between transmissive areas TA adjacent to each other in the first direction (for example, the X-axis direction). The second slit line SLb may be disposed between transmissive areas TA adjacent to each other in the second direction (for example, the Y-axis direction).

Furthermore, unlike the display area AA, the non-pad area NPAD may include the undercut structure UC under the overcoat layer 125 and on each of the first slit line SLa and the second slit line SLa. The undercut structure UC may ensure reliability by breaking the organic material layer on the overcoat layer 125. The undercut structure UC may be disposed under the overcoat layer 125 in an area where the organic material layer EL is disposed. The interlayer insulation layer 115 and the passivation layer 120 may be removed inwardly so that a side end E1 of the overcoat layer 125 protrudes beyond a side end E2 of the interlayer insulation layer 115 or the passivation layer 120, thereby forming the undercut structure UC. As shown in FIG. 5, the undercut structure UC may be disposed at a boundary of the display area EA at which the at least transmissive area TA and the display area EA are distinguished from each other.

The undercut structure UC may be formed by dry etching the passivation layer 120 and the interlayer insulating layer 115 and then performing a wet etching process the passivation layer 120 and the interlayer insulating layer 115 using a wet solution. The wet solution may include BOE (Buffered Oxide Etchant). The wet solution invades into the passivation layer 120 and the interlayer insulation layer 115 including the oxide and does not affect other components such as the overcoat layer 125. The wet solution may selectively remove only a portion of each of the passivation layer 120 and the interlayer insulation layer 115 to form the undercut structure UC.

Referring again to FIG. 5, the first slit line SLa may be disposed between the transmissive areas TA adjacent to each other in the first direction (e.g., the X-axis direction), while the second slit line SLb may be disposed between transmissive areas TA adjacent to each other in the second direction (e.g., the Y-axis direction). The first slit line SLa and the second slit line SLb may include the same material as that of the organic material layer EL.

The undercut structure UC may be disposed under a portion of the overcoat layer 125 on each of both opposing sides in the second direction of the first slit line SLa extending in the first direction. Alternatively, the undercut structure UC may be disposed under a portion of the overcoat layer 125 on each of both opposing sides in the first direction of the second slit line SLb extending in the second direction.

Referring to FIG. 5 and FIG. 6 together, the undercut structure UC may be disposed under a portion of the overcoat layer 125 on each of both opposing sides in the second direction (Y-axis direction) of the first slit line SLa extending in the first (X-axis) direction. The undercut structure UC may disconnect the first slit line SLa from a portion of the organic material layer EL on a portion of the overcoat layer 125 on each of both opposing sides in the second direction (Y-axis direction) of the first slit line SLa extending in the first (X-axis) direction, thereby preventing a moisture invasion path VP1 extending in the second direction (Y-axis) direction from being formed. Further, although not shown, the undercut structure UC may be disposed under a portion of the overcoat layer 125 on each of both opposing sides in the first direction of the second slit line SLa extending in the second direction. In this case, the undercut structure UC may disconnect the second slit line SLb from a portion of the organic material layer EL on a portion of the overcoat layer 125 on each of both opposing sides in the first direction (X-axis direction) of the second slit line SLb extending in the second (Y-axis) direction, thereby preventing another moisture invasion path VP2 extending in the first direction (X-axis) direction from being formed.

According to one aspect of the present disclosure, in the cuttable display panel PNL, the undercut structure UC may break the organic material layer disposed on the non-pad area NPAD, thereby preventing moisture or oxygen from invading the display area AA.

Accordingly, in a display device that is able to be cut to implement display devices of various sizes, the performance of the organic light-emitting element may be maintained for a long time by preventing the moisture from invading the display area AA. Furthermore, maintaining the performance of the organic light-emitting element for a long time may allow the image quality of the display device to be secured at low power, thereby reducing power consumption.

Referring again to FIGS. 2 to 5, in one aspect of the present disclosure, the bezel area BZ which may improve the reliability of the display panel PNL may be disposed at a border or edge of the display panel PNL where the non-display area NAA is located. The bezel area BZ may prevent the moisture invasion into the display area AA, thereby preventing the reliability of the display panel PNL from deteriorating. The bezel area BZ may have a closed loop shape surrounding the display area AA.

The bezel area BZ may be located along and at the edge of the display panel PNL and may include the reliable bezel area R_BZ, the non-pad bezel area NPAD_BZ, and the corner bezel area CN_BZ. The non-pad bezel area NPAD_BZ may be located between a cutting line CL and the display area AA. The corner bezel area CN_BZ may be disposed on a side end of the non-pad bezel area NPAD_BZ. In the cuttable display panel PNL, a plurality of transmissive areas and a plurality of display regions each including an organic material layer may be formed to extend to the non-pad area NPAD. Thus, each of the non-pad bezel area NPAD_BZ and the corner bezel area CN_BZ may include a plurality of transmissive areas and a plurality of display regions, each including the organic material layer.

The bezel area BZ may include a dam-applied area DMA. The dam-applied area DMA may be defined by a first barrier pattern BA1 disposed outside the outermost portion of the display area AA and a second barrier pattern BA2 disposed spaced apart from the first barrier pattern BA1 outwardly. The first barrier pattern BA1 may include a first lower pattern 125a as the outermost portion of the overcoat layer 125, and a first upper pattern 140a located on the first lower pattern 125a and constituting the outermost portion of a bank 140. The second barrier pattern BA2 may include a second lower pattern 125b and a second upper pattern 140b located on the second lower pattern 125b. The second lower pattern 125b may include the same material as that of the overcoat layer 125, and the second upper pattern 140b may include the same material as that of the bank 140. The second upper pattern 140b may be composed of a plurality of patterns arranged to be spaced apart from each other while being disposed on the second lower pattern 125b.

A dam pattern 200 may be disposed in the dam-applied area DMA disposed between the first barrier pattern BA1 and the second barrier pattern BA2. In one example, one surface of a portion of the dam pattern 200 disposed in the reliable bezel area BZ and between the first barrier pattern BA1 and the second barrier pattern BA2 may be in contact with an upper surface of the passivation layer 120, and the other surface thereof may be in contact with one surface of the second substrate 300. The first barrier pattern BA1, the second barrier pattern BA2, and the dam pattern 200 disposed therebetween prevent moisture from invading the display area AA.

A gate driver GD may be disposed in at least one edge of the display panel PNL. In one example, the gate driver GD may be located on one side of the display area AA. The gate driver GD may supply gate control signals to gate lines disposed in the display area AA. The gate driver GD may be disposed in a GIP (Gate-In-Panel) manner. The gate driver GD may be located to overlap a portion of the dam-applied area DMA.

The gate driver GD may include a gate driving circuit G_GIP and a dummy gate driving circuit DM_GIPa. The gate driving circuit G_GIP may include a plurality of gate driving patterns G_GIP_CPT and a plurality of gate driving wirings G_GIP_LN. The gate driver circuit G_GIP may be disposed on the buffer layer 110 (see FIG. 3). A plurality of circuit patterns CPT may be disposed on the buffer layer 110 in a distributed manner to supply signals for controlling pixels to the display area AA. For example, the circuit pattern CPT may apply power or signals to the gate driving pattern G_GIP_CPT via a connection wiring (not shown). The gate driving wiring G_GIP_LN, the gate driving pattern G_GIP_CPT, and the connection wiring may be located in the same layer.

The gate driving pattern G_GIP_CPT may supply the gate control signal or gate driving power supplied through the gate driving wiring G_GIP_LN to the pixels in the display area AA. In one example, the gate driving pattern G_GIP_CPT may be embodied as a thin-film transistor. Specifically, the thin-film transistor as the gate driving pattern G_GIP_CPT may include a structure similar to the thin-film transistor of the pixel in the display area AA. For example, the thin-film transistor as the gate driving pattern G_GIP_CPT may include a semiconductor layer, a gate electrode, a source electrode, and a drain electrode.

The dummy gate driving circuit DM_GIPa may be configured for a reset operation of a display unit located at the outermost position or a last stage of the display area AA. The dummy gate driving circuit DM_GIPa may include a plurality of dummy gate driving patterns DM_GIP_CPT. The plurality of dummy gate driving patterns GM_GIP_CPT of the dummy gate driving circuit DM_GIPa according to an aspect of the present disclosure may be arranged along the same direction as a direction in which the gate driving patterns G_GIP_CPT of the gate driving circuit G_GIP are arranged. For example, the plurality of dummy gate driving patterns DM_GIP_CPT of the dummy gate driving circuit DM_GIPa according to an aspect of the present disclosure may be arranged along the second direction (for example, the Y-axis direction or the longitudinal direction) of the display panel PNL, while the gate driving patterns G_GIP_CPT of the gate driving circuit G_GIP may be arranged in the second direction (for example, the Y-axis direction or the longitudinal direction) of the display panel PNL.

The dummy gate driving circuit DM_GIPa may include a plurality of dummy gate driving wirings DM_GIP_LN. The dummy gate driving wiring DM_GIP_LN may apply a reset signal to the dummy gate driving pattern DM_GIP_CPT. The dummy gate driving pattern DM_GIP_CPT may transmit the reset signal supplied through the dummy gate driving wiring DM_GIP_LN to the last stage of the display area AA. In one example, the dummy gate driving pattern DM_GIP_CPT may be embodied as a thin-film transistor. Specifically, the thin-film transistor as the dummy gate driving pattern DM_GIP_CPT may include a structure similar to that of the thin-film transistor of the pixel in the display area AA. For example, the thin-film transistor as the dummy gate driving pattern DM_GIP_CPT may include a semiconductor layer, a gate electrode, a source electrode, and a drain electrode.

The plurality of dummy gate driving patterns DM_GIP_CPT of the dummy gate driving circuit DM_GIPa according to an aspect of the present disclosure may be arranged along the same direction, that is, the second direction (for example, the Y-axis direction or the longitudinal direction) of the display panel PNL as the direction in which the gate driving patterns G_GIP_CPT of the gate driving circuit G_GIP are arranged. Both the gate driving circuit G_GIP and the dummy gate driving circuit DM_GIPa may be located in an overcoat layer formation area OCA. Accordingly, each of the gate driving circuit G_GIP and the dummy gate driving circuit DM_GIPa may be disposed to vertically overlap the overcoat layer 125.

Referring to FIG. 2 and FIG. 4, the dummy gate driving circuit DM_GIPa may be disposed in the corner bezel area CN_BZ. Like the non-pad bezel area NPAD_BZ, the corner bezel area CN_BZ may include a pattern array structure to break the organic material layer to prevent moisture invasion into the display area. For example, the undercut structure UC may be disposed under the overcoat layer 125 disposed in the non-pad bezel area NPAD_BZ. Further, in the corner bezel area CN_BZ, the undercut structure UC may be disposed under the overcoat layer 125 in the same way as in the non-pad bezel area NPAD_BZ.

The undercut structure UC disposed under the overcoat layer 125 serves to break the organic material layer EL which include the organic material that may act as a moisture invasion path in the non-pad bezel area NPAD_BZ or the corner bezel area CN_BZ.

The overcoat layer formation area OCA where the overcoat layer 125 is formed may include an area where the gate driver GD is disposed and thus may protect the gate driver GD. In the overcoat layer formation area OCA, a boundary EG_OC of the overcoat layer may be aligned with a side end of each of the gate driver GD and the corner bezel area CN_BZ. The boundary EG_OC of the overcoat layer may refer to a side end of the overcoat layer covering the gate driver GD.

Referring again to FIG. 2 and FIG. 4, the dummy gate driving circuit DM_GIPa may be disposed to overlap the overcoat layer formation area OCA where the overcoat layer 125 is formed. Accordingly, the undercut structure UC and the slit line SL disposed under the overcoat layer 125 may be disposed in the same layer as a layer in which the dummy gate driving circuit DM_GIPa is disposed. For example, the slit line SL may be located between the dummy gate driving wiring DM_GIP_LN and the dummy gate driving pattern DM_GIP_CPT of the dummy gate driving circuit DM_GIPa. In this case, due to the presence of the slit line SL, it may be difficult to electrically connect the dummy gate driving wiring DM_GIP_LN and the dummy gate driving pattern DM_GIP_CPT to each other.

Accordingly, in one aspect of the present disclosure, the dummy gate driving wiring DM_GIP_LN and the dummy gate driving pattern DM_GIP_CPT may be electrically connected to each other via the first metal wiring line LS. In one example, at least one or more first metal wiring lines LS may be disposed on the first substrate 100. One first metal wiring line LS may be disposed between the dummy gate driving wiring DM_GIP_LN and the dummy gate driving pattern DM_GIP_CPT. Furthermore, another first metal wiring line LS may be disposed between adjacent dummy gate driving patterns DM_GIP_CPT. The first metal wiring line LS may be covered with the buffer layer 110. The first metal wiring line LS may be disposed on a different layer from a layer in which the dummy gate driving wiring DM_GIP_LN and the dummy gate driving pattern DM_GIP_CPT are disposed.

Each of the first metal wiring lines LS may be electrically connected to the dummy gate driving wiring DM_GIP_LN and the dummy gate driving pattern DM_GIP_CPT via a contact electrode CT extending through the buffer layer 110. Further, the dummy gate driving wiring DM_GIP_LN and the dummy gate driving pattern DM_GIP_CPT may be electrically connected to each other via the first metal wiring line LS. Accordingly, when the undercut structure UC and the slit line SL disposed under the overcoat layer 125 are disposed on the same layer as the layer in which the dummy gate driving circuit DM_GIPa is disposed, the dummy gate driving pattern DM_GIP_CPT and the dummy gate driving wiring DM_GIP_LN of the dummy gate driving circuit DM_GIPa may be electrically connected to each other via the first metal wiring lines LS disposed on the layer different from the layer in which the dummy gate driving circuit DM_GIPa is disposed in the distributed manner. Furthermore, constructing a pattern array in which components of the dummy gate driving circuit may be electrically connected to each other via the first metal wiring line LS may allow the integrated pattern array to be divided in the distributed manner.

In one example, the cathode electrode 150 disposed on top of the overcoat layer 125 may be formed using a sputtering manner. The sputtering deposition process has excellent step coverage, thereby allowing the cathode electrode to be deposited on an entirety of an exposed surface of the undercut structure UC. Then, the cathode electrode 150 may be deposited on the wiring of the dummy gate driving circuit DM_GIPa which is disposed to overlap the undercut structure. As a result, there is a case where the cathode electrode 150 and the wiring of the dummy gate driving circuit DM_GIPa are electrically connected to each other, thereby causing the dummy gate driving circuit DM_GIPa to be electrically short-circuited.

Furthermore, the gate driving patterns of the dummy gate driving circuit DM_GIPa are arranged in the same direction (e.g., the second direction, the longitudinal or Y-axis direction of the display panel) as the direction in which the gate driving patterns of the gate driving circuit GIP are arranged. Thus, the dummy gate driving circuit DM_GIPa may be disposed to extend to an area where reliability may be secured within the corner bezel area CN_BZ. For example, as shown in FIG. 2, the dummy gate driving circuit DM_GIPa may be disposed to extend from the corner bezel area CN_BZ to a position adjacent to the second barrier pattern BA2. As a result, the area where reliability may be secured within the corner bezel area CN_BZ may be reduced compared to the area where reliability may be secured within the non-pad bezel area NPAD_BZ. When the area where reliability may be secured within the corner bezel area CN_BZ decreases, the area of the moisture invasion path through which moisture invades may increase by an amount of the reduced area size. In this case, the reliability of the display panel PNL may be reduced.

Accordingly, in another aspect of the present disclosure, the dummy gate driving circuit may be prevented from being electrically short-circuited. Furthermore, the reliability of the display panel may be improved by improving the area size of the corner bezel area.

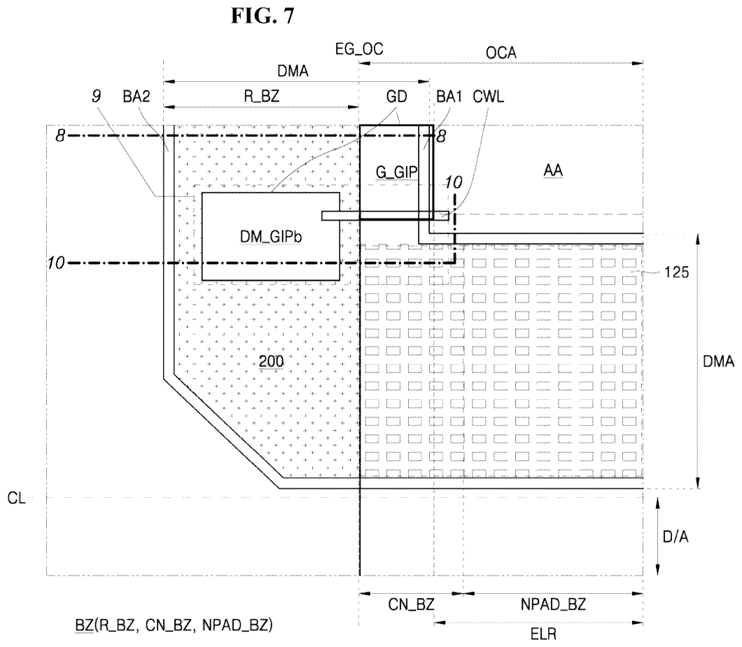

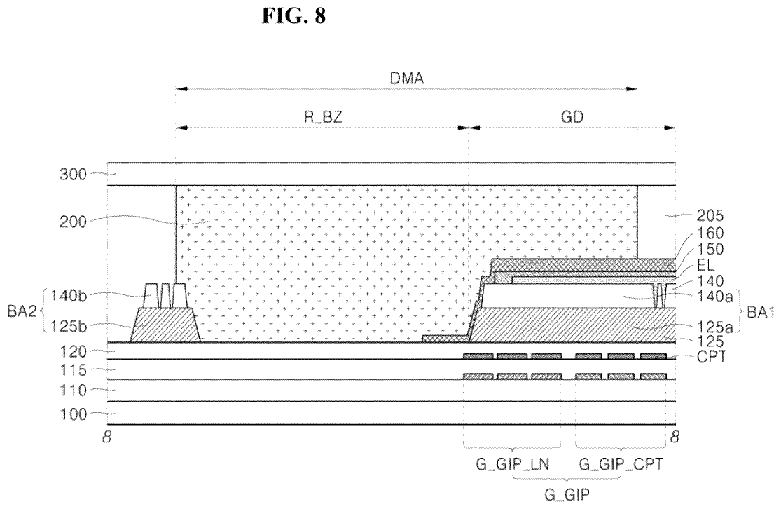

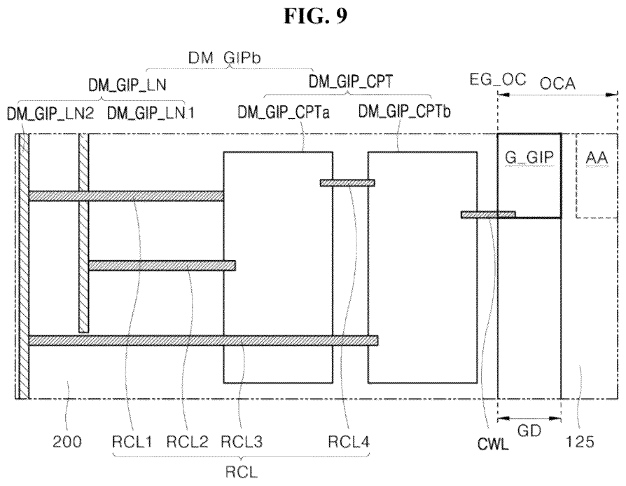

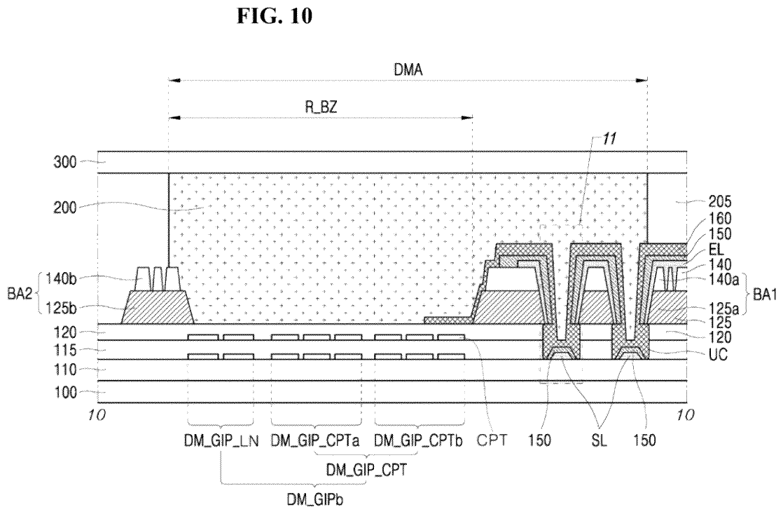

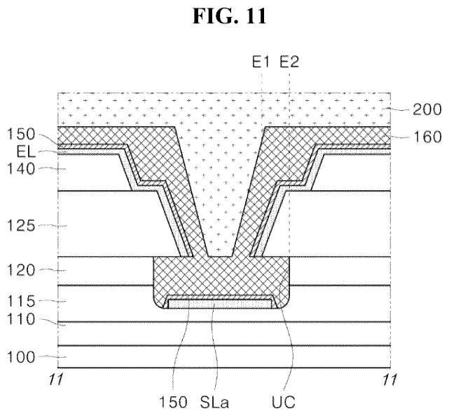

FIG. 7 is an enlarged plan view of a portion of the non-pad area of a display device according to another aspect of the present disclosure. FIG. 8 is a cross-sectional view along a line 8-8 in FIG. 7. FIG. 9 is an enlarged view of an area 9 in FIG. 7. For example, FIG. 9 is an enlarged view of the area where the dummy gate driving circuit is disposed. FIG. 10 is a cross-sectional view along a line 10-10 in FIG. 7. FIG. 11 is an enlarged cross-sectional view of an area 11 in FIG. 10. The same reference numbers previously used with reference to FIGS. 2 to 6 indicate the same components. Thus, descriptions thereof are omitted.

Referring to FIG. 7 and FIG. 8, the gate driver GD may be disposed in the non-display area NAA on one side of the display area AA. The gate driver GD may supply gate control signals to gate lines disposed in the display area AA. The gate driver GD may be located to overlap the dam-applied area DMA.

The gate driver GD may include the gate driving circuit G_GIP and the dummy gate driving circuit DM_GIPa. The gate driving circuit G_GIP may include the plurality of gate driving patterns G_GIP_CPT and the plurality of gate driving wirings G_GIP_LN. The gate driver circuit G_GIP may be disposed on the buffer layer 110 (see FIG. 8). The gate driving wiring G_GIP_LN may apply power or signals to the gate driving pattern G_GIP_CPT via the connection wiring (not shown). The gate driving wiring G_GIP_LN, the gate driving pattern G_GIP_CPT, and the connection wiring may be located in the same layer.

The gate driving pattern G_GIP_CPT may supply the gate control signal or gate driving power supplied through the gate driving wiring G_GIP_LN to the pixels in the display area AA. In one example, the gate driving pattern G_GIP_CPT may be embodied as a thin-film transistor. Specifically, the thin-film transistor as the gate driving pattern G_GIP_CPT may include a structure similar to that of the thin-film transistor of the pixel in the display area AA. For example, the thin-film transistor as the gate driving pattern G_GIP_CPT may include a semiconductor layer, a gate electrode, a source electrode, and a drain electrode. The gate driving circuit G_GIP may be located in the overcoat layer formation area OCA. Accordingly, as shown in FIG. 8, the gate driving circuit G_GIP may be disposed to vertically overlap with the overcoat layer 125.

The dummy gate driving circuit DM_GIPb may be configured for a reset operation of the display unit located at the outermost position or the last stage of the display area AA.

Referring to FIG. 9 to FIG. 11 along with FIG. 7, the dummy gate driving circuit DM_GIPb may be disposed outwardly of the overcoat layer boundary EG_OC. In one example, the dummy gate driving circuit DM_GIPb according to another aspect of the present disclosure may be disposed outwardly of the overcoat layer boundary EG_OC and does not overlap the overcoat layer 125 vertically. Additionally, the dummy gate driving circuit DM_GIPb may be located in the dam-applied area DMA. For example, the dummy gate driving circuit DM_GIPb may be disposed in the reliable bezel area R_BZ and in the dam-applied area DMA, as shown in FIG. 10.

The dummy gate driving circuit DM_GIPb may include the plurality of dummy gate driving patterns DM_GIP_CPT and the plurality of dummy gate driving wiring DM_GIP_LN. The plurality of dummy gate driving patterns DM_GIP_CPT may include a first dummy gate driving pattern DM_GIP_CPTa and a second dummy gate driving pattern DM_GIP_CPTb.

The first dummy gate driving pattern DM_GIP_CPTa and the second dummy gate driving pattern DM_GIP_CPTb may be positioned to be spaced apart from each other. For example, the first dummy gate driving pattern DM_GIP_CPTa and the second dummy gate driving pattern DM_GIP_CPTb may be arranged to be spaced apart from each other in the first direction (e. g., the X-axis direction or a width direction).

The plurality of dummy gate driving wirings DM_GIP_LN may be disposed in a portion of the bezel area spaced from the first dummy gate driving pattern DM_GIP_CPTa and the second dummy gate driving pattern DM_GIP_CPTb. The plurality of dummy gate driving wirings DM_GIP_LN may include a first dummy gate driving wiring DM_GIP_LN1 and a second dummy gate driving wiring DM_GIP_LN2. The reset signal output from each of the plurality of dummy gate driving wirings DM_GIP_LN may be transmitted to the first dummy gate driving pattern DM_GIP_CPTa and the second dummy gate driving pattern DM_GIP_CPTb via a plurality of reset signal supply lines RCL1, RCL2, RCL3, and RCL4 and then may be transmitted to the last stage of the display area AA via a connection wiring line CWL.

Referring to FIG. 10 and FIG. 11 along with FIG. 7, a pattern array structure for preventing the moisture invasion into the display area AA may be disposed in the corner bezel area CN_BZ and the non-pad bezel area NPAD_BZ. For example, the pattern array structure for preventing the moisture invasion into the display area AA may include the overcoat layer 125 having the undercut structure UC disposed thereunder and the slit line SL. The undercut structure UC disposed under the overcoat layer 125 serves to break the moisture invasion path by breaking the organic material layer EL in the non-pad bezel area NPAD_BZ and corner bezel area CN_BZ.

The buffer layer 110, the interlayer insulating layer 115, and the passivation layer 120 disposed on the first substrate 100 may be disposed under the overcoat layer 125. The bank 140, the organic material layer EL, the cathode electrode 150, and a capping layer 160 may be disposed on top of the overcoat layer 125.

The interlayer insulation layer 115 and the passivation layer 120 may be removed inwardly so that a side end E1 of the overcoat layer 120 protrudes beyond a side end E2 of the interlayer insulation layer 115 or the passivation layer 120, thereby forming the undercut structure UC. The capping layer 160 may be formed to fill a space defined by the undercut structure UC. However, aspects of the present disclosure are not limited thereto.

According to another aspect of the present disclosure, the dummy gate driving circuit DM_GIPb may be disposed in the same layer as a layer in which the undercut structure UC and the slit line SL are disposed. The dummy gate driving circuit DM_GIPb may be located in the reliable bezel area R_BZ while non-overlapping the overcoat layer formation area OCA. One surface of a portion of the dam pattern 200 disposed in the reliable bezel area R_BZ may be in contact with an upper surface of the passivation layer 120, and the other surface thereof may be in contact with one surface of the second substrate 300. Accordingly, the dam pattern 200 may protect the dummy gate driving circuit DM_GIPb.

That is, the dummy gate driving circuit DM_GIPb may be disposed in the reliable bezel area R_BZ having a relatively larger area size than that of the area where the gate driving circuit G_GIP is disposed. Accordingly, the first dummy gate driving pattern DM_GIP_CPTa and the second dummy gate driving pattern DM_GIP_CPTb may be arranged in the distributed manner in the first direction in the reliable bezel area R_BZ. The plurality of dummy gate driving wirings DM_GIP_LN for supplying the reset signal may be disposed in the same layer as a layer in which the first dummy gate driving pattern DM_GIP_CPTa and the second dummy gate driving pattern DM_GIP_CPTb of the gate dummy driving circuit DM_GIPb are disposed. Furthermore, the dummy gate driving circuit DM_GIPb may be disposed in the same layer as the layer in which the undercut structure UC and the slit line SL acting as the moisture invasion prevention pattern layer are disposed.

As shown in FIG. 4, when the dummy gate driving circuit DM_GIPa is disposed on the overcoat layer formation area OCA and thus is disposed in the same layer as the layer in which the undercut structure UC (see FIG. 4) and the slit line SL (see FIG. 4) are disposed, the components the dummy gate driving circuits DM_GIPa may not be electrically connected to each other, thereby requiring the first metal wiring line LS (see FIG. 4) as the connection wiring line.

On the contrary, according to another aspect of the present disclosure, the dummy gate driving circuit DM_GIPb is disposed in the reliable bezel area R_BZ having a relatively larger area size than that of the area where the undercut structure UC and the slit line SL are disposed, such that the first metal wiring line LS serving as the connection pattern may be omitted. The first metal wiring line LS may be omitted, thereby simplifying the process.

Furthermore, when the gate driving patterns of the dummy gate driving circuit DM_GIPb are arranged in the same direction as the direction in which the gate driving patterns of the gate driving circuit G_GIP are arranged, the dummy gate driving circuit DM_GIPb is disposed in the corner bezel area CN_BZ. Thus, an area size of the corner bezel area CN_BZ is reduced by an area size of the area where the dummy gate driving circuit DM_GIPb is disposed in the corner bezel area CN_BZ. When the area size of the corner bezel area CN_BZ is reduced, the area size of the moisture invasion path through which moisture invades may increase by an amount of the reduced area.

On the contrary, in another aspect of the present disclosure, the dummy gate driving circuit DM_GIPb is disposed outwardly of the overcoat layer boundary EG_OC. As a result, the area size of the corner bezel area CN_BZ increases, which may have the effect of delaying the moisture invasion.

Furthermore, as the dummy gate driving circuit DM_GIPb is disposed outwardly of the overcoat layer boundary EG_OC, only a pattern array structure for preventing the moisture penetration into the display area may be disposed in the corner bezel area CN_BZ, as in the non-pad bezel area NPAD_BZ. Accordingly, the reliability of the display device may be improved by breaking the moisture invasion path to the display area AA.

Furthermore, the overcoat layer having the undercut structure defined thereunder is disposed in the non-pad bezel area NPAD_BZ or corner bezel area CN_BZ. Thus, the organic material layer disposed above the slit line disposed between neighboring transmissive areas is broken, thereby preventing the moisture invasion path from being formed due to the slit line.

An aspect and aspects of the display device according to the present disclosure may be described as follows.

One aspect of the present disclosure provides a display device comprising: a display panel including a display area, a non-display area surrounding the display area, and a non-pad area located outside the display area; a dam-applied area disposed in the non-display area to surround the display area; a gate driver disposed in at least one side of the non-display area; and an overcoat layer disposed in the display area and the non-pad area, and on the gate driver, wherein the gate driver includes a gate driving circuit and a dummy gate driving circuit.

In accordance with some aspects of the display device, the non-pad area includes: a non-pad bezel area located on one side of the display area, wherein a moisture invasion prevention pattern array structure including a plurality of transmissive areas and a plurality of display areas is disposed, wherein each of the plurality of transmissive areas and the plurality of display areas includes an organic material layer, wherein each of the plurality of display areas includes the overcoat layer; and a corner bezel area located outside the non-pad bezel area, wherein an outer side end of the overcoat layer is aligned with an outer side end of the corner bezel area, wherein the moisture invasion prevention pattern array structure includes an undercut structure disposed under the overcoat layer.

In accordance with some aspects of the display device, the moisture invasion prevention pattern array structure including the plurality of transmissive areas and the plurality of display areas is further disposed in the corner bezel area, wherein the moisture invasion prevention pattern array structure includes the undercut structure disposed under the overcoat layer.

In accordance with some aspects of the display device, the plurality of transmissive areas is arranged to be spaced apart from each other in a first direction and a second direction different from the first direction, and each of the display areas is disposed between adjacent ones of the plurality of transmissive areas, wherein the plurality of transmissive areas further includes a plurality of slit lines, wherein each of the slit lines is disposed between adjacent ones of the transmissive areas, wherein the slit lines include a first slit line disposed between transmissive areas adjacent to each other in the first direction and a second slit line disposed between transmissive areas adjacent to each other in the second direction.

In accordance with some aspects of the display device, the undercut structure is disposed under the overcoat layer, and the organic material layer is located on top of the overcoat layer, wherein a side end of the organic material layer is aligned with a side end of the overcoat layer protruding inwardly beyond a side end of the undercut structure.

In accordance with some aspects of the display device, the undercut structure is located at least at a boundary of the display area distinguishing the transmissive area and the display area from each other.

In accordance with some aspects of the display device, the gate driving circuit extends along a longitudinal direction of the display panel, wherein the dummy gate driving circuit extends along the longitudinal direction of the display panel.

In accordance with some aspects of the display device, the gate driving circuit includes a plurality of gate driving patterns and a plurality of gate driving wirings, wherein the dummy gate driving circuit includes a plurality of dummy gate driving patterns and a plurality of dummy gate driving wirings, wherein the plurality of gate driving patterns, the plurality of gate driving wirings, the plurality of dummy gate driving patterns, and the plurality of dummy gate driving wirings are disposed in the same layer.

In accordance with some aspects of the display device, the display device further comprises: a metal wiring line disposed in a different layer from the layer in which the plurality of gate driving patterns, the plurality of gate driving wirings, the plurality of dummy gate driving patterns, and the plurality of dummy gate driving wirings are disposed; and a contact electrode electrically connecting each of the dummy gate driving pattern and the dummy gate driving wiring to the metal wiring line.

In accordance with some aspects of the display device, the gate driving circuit extends along a first direction as a longitudinal direction of the display panel, wherein the dummy gate driving circuit extends along a second direction as a width direction of the display panel, wherein the dummy gate driving circuit is disposed outwardly of an outermost portion of the overcoat layer covering the gate driver.

In accordance with some aspects of the display device, the dummy gate driving circuit is located in the dam-applied area and vertically non-overlaps the overcoat layer.

In accordance with some aspects of the display device, the dummy gate driving circuit includes a plurality of dummy gate driving patterns and a plurality of dummy gate driving wirings, wherein the plurality of dummy gate driving patterns includes a first dummy gate driving pattern and a second dummy gate driving pattern spaced apart from the first dummy gate driving pattern, wherein the first dummy gate driving pattern and the second dummy gate driving pattern are arranged in the second direction different from the first direction.

In accordance with some aspects of the display device, the plurality of dummy gate driving wirings includes first and second dummy gate driving wirings spaced apart from the first and second dummy gate driving patterns and outputting a reset signal, wherein the display device further comprises: a plurality of reset signal supply lines for supplying the reset signal output from the plurality of dummy gate driving wirings to each of the first and second dummy gate driving patterns; and a connection wiring line for transmitting the reset signal supplied from the plurality of reset signal supply lines to the display area.

In accordance with some aspects of the display device, the plurality of dummy gate driving patterns and the plurality of dummy gate driving wiring are disposed in the same layer as a layer in which the undercut structure is disposed.

In accordance with some aspects of the display device, the display device further comprises: a pad area disposed on one side of the display panel opposite to the non-pad area; and a cutting line located outside the non-pad area, wherein the cutting line is constructed to control a size of the display panel.

Although the aspects of the present disclosure have been described in more detail with reference to the accompanying drawings, the present disclosure is not necessarily limited to these aspects, and may be modified in a various manner within the scope of the technical spirit of the present disclosure. Accordingly, the aspects as disclosed in the present disclosure are intended to describe rather than limit the technical idea of the present disclosure, and the scope of the technical idea of the present disclosure is not limited by these aspects. Therefore, it should be understood that the aspects described above are not restrictive but illustrative in all respects, and it is intended that the present disclosure covers the modifications and variations of the aspects provided they come within the scope of the appended claims and their equivalents.

What is claimed is:

1. A display device comprising:
a display panel including a display area, a non-display area surrounding the display area, and a non-pad area located outside the display area;
a dam-applied area disposed in the non-display area and surrounding the display area;
a gate driver disposed in at least one side of the non-display area; and
an overcoat layer disposed in the display area and the non-pad area, and disposed on the gate driver,
wherein the gate driver includes a gate driving circuit and a dummy gate driving circuit.

2. The display device of claim 1, wherein the non-pad area includes:
a non-pad bezel area located on one side of the display area;
a moisture invasion prevention pattern array structure including a plurality of transmissive areas and a plurality of display areas is disposed, wherein each of the plurality of transmissive areas and the plurality of display areas includes an organic material layer, and wherein each of the plurality of display areas includes the overcoat layer; and
a corner bezel area located outside the non-pad bezel area, wherein an outer side end of the overcoat layer is aligned with an outer side end of the corner bezel area,
wherein the moisture invasion prevention pattern array structure includes an undercut structure disposed under the overcoat layer.

3. The display device of claim 2, wherein the moisture invasion prevention pattern array structure including the plurality of transmissive areas and the plurality of display areas is further disposed in the corner bezel area, and
wherein the moisture invasion prevention pattern array structure includes the undercut structure disposed under the overcoat layer.

4. The display device of claim 2, wherein the plurality of transmissive areas is spaced apart from each other in a first direction and a second direction different from the first direction, and each of the display areas is disposed between adjacent ones of the plurality of transmissive areas,
wherein the plurality of transmissive areas further includes a plurality of slit lines,
wherein each of the slit lines is disposed between adjacent ones of the transmissive areas, and
wherein the slit lines include a first slit line disposed between transmissive areas adjacent to each other in the first direction and a second slit line disposed between transmissive areas adjacent to each other in the second direction.

5. The display device of claim 2, wherein the undercut structure is disposed under the overcoat layer, and the organic material layer is located on top of the overcoat layer, and
wherein a side end of the organic material layer is aligned with a side end of the overcoat layer protruding inwardly beyond a side end of the undercut structure.

6. The display device of claim 5, wherein the undercut structure is located in at least at a boundary of the display area distinguishing the transmissive area and the display area from each other.

7. The display device of claim 5, wherein the gate driving circuit extends along a longitudinal direction of the display panel, and
wherein the dummy gate driving circuit extends along the longitudinal direction of the display panel.

8. The display device of claim 2, wherein the gate driving circuit includes a plurality of gate driving patterns and a plurality of gate driving wirings,
wherein the dummy gate driving circuit includes a plurality of dummy gate driving patterns and a plurality of dummy gate driving wirings, and
wherein the plurality of gate driving patterns, the plurality of gate driving wirings, the plurality of dummy gate driving patterns, and the plurality of dummy gate driving wirings are disposed at a same layer.

9. The display device of claim 8, wherein the display device further comprises:
a metal wiring line disposed in a different layer from the layer in which the plurality of gate driving patterns, the plurality of gate driving wirings, the plurality of dummy gate driving patterns, and the plurality of dummy gate driving wirings are disposed; and
a contact electrode electrically connecting each of the dummy gate driving pattern and the dummy gate driving wiring to the metal wiring line.

10. The display device of claim 2, wherein the gate driving circuit extends along a first direction as a longitudinal direction of the display panel,
wherein the dummy gate driving circuit extends along a first direction as a width direction of the display panel, and
wherein the dummy gate driving circuit is disposed outwardly of an outermost portion of the overcoat layer covering the gate driver.

11. The display device of claim 10, wherein the dummy gate driving circuit is located in the dam-applied area and vertically non-overlaps the overcoat layer.

12. The display device of claim 10, wherein the dummy gate driving circuit includes a plurality of dummy gate driving patterns and a plurality of dummy gate driving wirings,
wherein the plurality of dummy gate driving patterns includes a first dummy gate driving pattern and a second dummy gate driving pattern spaced apart from the first dummy gate driving pattern, and
wherein the first dummy gate driving pattern and the second dummy gate driving pattern are arranged in the first direction different from the second direction.

13. The display device of claim 12, wherein the plurality of dummy gate driving wirings includes first and second dummy gate driving wirings spaced apart from the first and second dummy gate driving patterns and outputting a reset signal, and
wherein the display device further comprises:
a plurality of reset signal supply lines supplying the reset signal output from the plurality of dummy gate driving wirings to each of the first and second dummy gate driving patterns; and
a connection wiring line transmitting the reset signal supplied from the plurality of reset signal supply lines to the display area.

14. The display device of claim 12, wherein the plurality of dummy gate driving patterns and the plurality of dummy gate driving wiring are disposed at a same layer as a layer in which the undercut structure is disposed.

15. The display device of claim 1, wherein the display device further comprises:
a pad area disposed on one side of the display panel opposite to the non-pad area; and
a cutting line located outside the non-pad area, and
wherein the cutting line is constructed to control a size of the display panel.
